(19) United States
(12) Patent Application Publication
(10) Pub. No.: US 2016/0126172 A1
(43) Pub. Date: May 5, 2016

(54) SEMICONDUCTOR DEVICE PACKAGE AND ELECTRONIC DEVICE INCLUDING THE SAME

(71) Applicant: KABUSHIKI KAISHA TOSHIBA, Tokyo (JP)

(72) Inventors: Nobuhiro YAMAMOTO, Yokohama Kanagawa (JP); Keiko KAJI, Kawasaki Kanagawa (JP); Kiyokazu ISHIZAKI, Akishima Tokyo (JP); Takahisa FUNAYAMA, Musashino Tokyo (JP)

(21) Appl. No.: 14/636,177

(22) Filed: Mar. 2, 2015

(30) Foreign Application Priority Data
Oct. 30, 2014 (JP) 2014-221446

(51) Int. Cl. H01L 23/498; H01L 25/10; H01L 25/065; H01L 23/48; H01L 23/31; H01L 25/18

(52) U.S. Cl. CPC H01L 23/49816; H01L 23/49833; H01L 23/3107; H01L 23/49838; H01L 25/18; H01L 25/0657; H01L 23/481; H01L 25/105; H01L 2225/06541

(57) ABSTRACT

A semiconductor device package includes a substrate having a first surface and a second surface that is opposite to the first surface, a plurality of solder joints disposed on the first surface of the substrate, a semiconductor chip disposed above the second surface of the substrate, and a support member disposed between the second surface of the substrate and the semiconductor chip. At least one of the solder joints is in contact with the first surface of the substrate opposite to a region on the second surface in which the support member is not disposed.

### CROSS-REFERENCE TO RELATED APPLICATION

This application is based upon and claims the benefit of priority from Japanese Patent Application No. 2014-221446, filed Oct. 30, 2014, the entire contents of which are incorporated herein by reference.

### FIELD

Embodiments described herein relate generally to a semiconductor device package.

### BACKGROUND

A semiconductor device package includes a solder joint connecting the semiconductor device package to a circuit substrate.

### DESCRIPTION OF THE DRAWINGS

FIG. 1 is a perspective view of a semiconductor device and a host device according to a first embodiment.

FIG. 2 is a block diagram of a system structure of a semiconductor package illustrated in FIG. 1.

FIG. 3 is a perspective view of an electronic device including the semiconductor package according to the first embodiment.

FIG. 4 is a cross-sectional view of the semiconductor package according to the first embodiment.

FIG. 5 is a top plan view of the semiconductor package according to the first embodiment.

FIG. 6 is a cross-sectional view of the semiconductor package according to the first embodiment when a circuit substrate deforms.

FIG. 7 is a cross-sectional view of a semiconductor package according to a first modified example of the first embodiment.

FIG. 8 is a cross-sectional view of a semiconductor package according to a second modified example of the first embodiment.

FIG. 9 is a cross-sectional view of a semiconductor package according to a third modified example of the first embodiment.

FIG. 10 is a cross-sectional view illustrating a semiconductor package according to a second embodiment.

FIG. 11 is a cross-sectional enlarged view of a support portion illustrated in FIG. 10.

FIG. 12 is a cross-sectional view of a semiconductor package according to a third embodiment.

FIG. 13 is a cross-sectional view of a semiconductor package according to a fourth embodiment.

FIG. 14 is a top plan view of a semiconductor package according to a fifth embodiment.

FIG. 15 is a cross-sectional view of a semiconductor package according to a sixth embodiment.

FIG. 16 is a cross-sectional view of a semiconductor package according to a seventh embodiment.

FIG. 17 is a top plan view of the semiconductor package according to the seventh embodiment.

FIG. 18 is a cross-sectional view of a semiconductor package according to an eighth embodiment.

### DETAILED DESCRIPTION

A semiconductor package is expected to be more reliable.

One or more of exemplary embodiments provide a semiconductor package capable of improving reliability.

In general, according to one embodiment, a semiconductor device package includes a substrate having a first surface and a second surface that is opposite to the first surface, a plurality of solder joints disposed on the first surface of the substrate, a semiconductor chip disposed above the second surface of the substrate, and a support member disposed between the second surface of the substrate and the semiconductor chip. At least one of the solder joints is in contact with the first surface of the substrate opposite to a region on the second surface in which the support member is not disposed.

Hereinafter, embodiments will be described with reference to the drawings.

In this disclosure, some elements are represented using the expression “a plurality of” by example. This expression is only an example and the above elements may be represented in another expression. Further, the elements without the expression “a plurality of” may be represented in another expression.

Further, the drawings are schematic and a relation between thickness and measurement on the plane surface and ratio of thickness of each layer may be different from the actual ones. The drawings may contain a portion mutually different in the measurement relation and ratio.

### First Embodiment

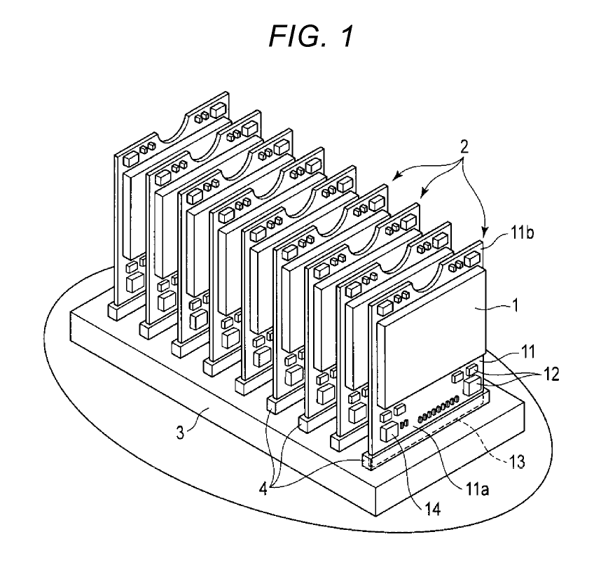

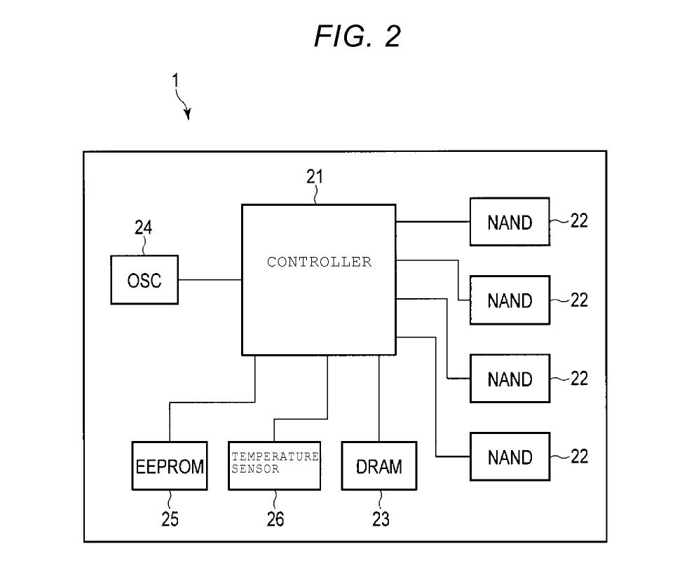

FIGS. 1 and 2 illustrate an example of a semiconductor device 2 with a semiconductor package 1 according to a first embodiment mounted thereon. The semiconductor device 2 is an example of “semiconductor module” or “semiconductor memory device.” The semiconductor device 2 is, for example, a Solid State Drive (SSD) but not restricted to the SSD.

As illustrated in FIG. 1, the semiconductor device 2 becomes usable by being mounted on, for example, a host device 3 such as a server. The host device 3 includes a plurality of connectors 4 (for example, slots). The respective semiconductor devices 2 are attached to the respective connectors 4 of the host device 3. The semiconductor device 2 includes a circuit substrate 11, a semiconductor package 1, and a plurality of electronic components 12.

The circuit substrate 11 is formed, for example, in a shape of rectangular flat plate. The circuit substrate 11 includes a first end 11a and a second end 11b positioned at the side opposite to the first end 11a. The first end 11a includes an interface portion 13 (terminal portion, connecting portion). The interface portion 13 includes, for example, a plurality of connection terminals (metal terminals). The interface portion 13 is inserted into the connector 4 of the host device 3 and electrically connected to the connector 4. The interface portion 13 exchanges signals (control signals and data signals) between the interface portion 13 and the host device 3.

The electronic components 12 mounted on the circuit substrate 11 include, for example, a power source component 14 (power source IC), a capacitor, and a resistor. The power source component 14 is, for example, a DC-DC converter, which generates a predetermined voltage necessary for the semiconductor package 1 from the power supplied from the host device 3.

The semiconductor package 1 is mounted on the circuit substrate 11. One example of the semiconductor package 1 is System in Package (SiP) type module, and a plurality of silicon chips (semiconductor chips) are sealed within one package.

The semiconductor package 1 is, for example, Ball Grid Array-Solid State Drive (BGA-SSD), and a plurality of semiconductor memories and a controller are formed integrally as one BGA type package.

FIG. 2 illustrates one example of a system structure of the semiconductor package 1. The semiconductor package 1 includes a controller 21, a plurality of semiconductor memories 22, a Dynamic Random Access Memory (DRAM) 23, an oscillator (OSC) 24, an Electrically Erasable and Programmable ROM (EEPROM) 25, and a temperature sensor 26. Each of the controller 21, the semiconductor memories 22, and the DRAM 23 is one example of a “silicon chip (semiconductor chip).”

The controller 21 controls, for example, operations of the plural semiconductor memories 22. Specifically, the controller 21 controls writing, reading, and erasing of data with respect to the plural semiconductor memories 22. Each of the semiconductor memories 22 is, for example, a NAND memory (NAND type flash memory). The NAND memory is one example of a nonvolatile memory. The DRAM 23 is one example of “data transfer portion.” The DRAM 23 is one example of a nonvolatile memory, used for storing control information of the semiconductor memories 22 and caching data.

The oscillator 24 supplies an operation signal of a predetermined frequency to the controller 21. The EEPROM 25 stores a control program and the like as fixed information. The temperature sensor 26 detects a temperature within the semiconductor package 1 and notifies the controller 21 of the temperature.

A semiconductor package to which the structure according to the embodiment may be applied is not restricted to the above example, but, for example, one package may accommodate one silicon chip in a sealed way.

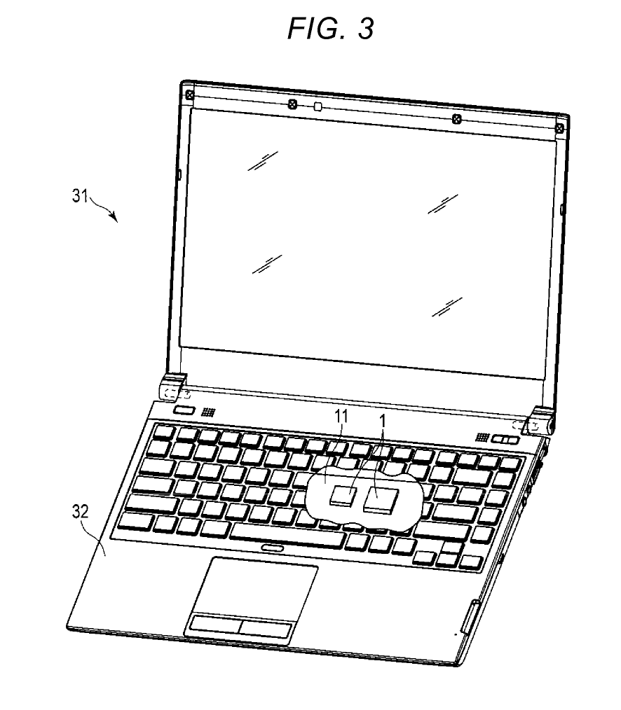

FIG. 3 illustrates one example of an electronic device 31 on which the semiconductor package 1 according to the first embodiment is mounted. The electronic device 31 is, for example, a notebook-type portable computer but not restricted to this; the electronic device 31 may be, for example, a tablet terminal (multi-function portable terminal), a smart phone, various kinds of wearable devices, and a television receiver.

The electronic device 31 includes a case body 32 and a circuit substrate 11 accommodated in the case body 32. The semiconductor package 1 is mounted on the circuit substrate 11. The semiconductor package 1 may be a storage component as mentioned above or a controller component like CPU. As mentioned above, the semiconductor package 1 according to the embodiment may be widely applied to various devices including the semiconductor device 2 and the electronic device 31.

Next, the semiconductor package 1 according to the embodiment will be described in detail.

For the sake of convenience, an example of one package accommodating one silicon chip in a sealed way will be described. The structure described below may be also applied to a type of one package accommodating a plurality of silicon chips in a sealed way.

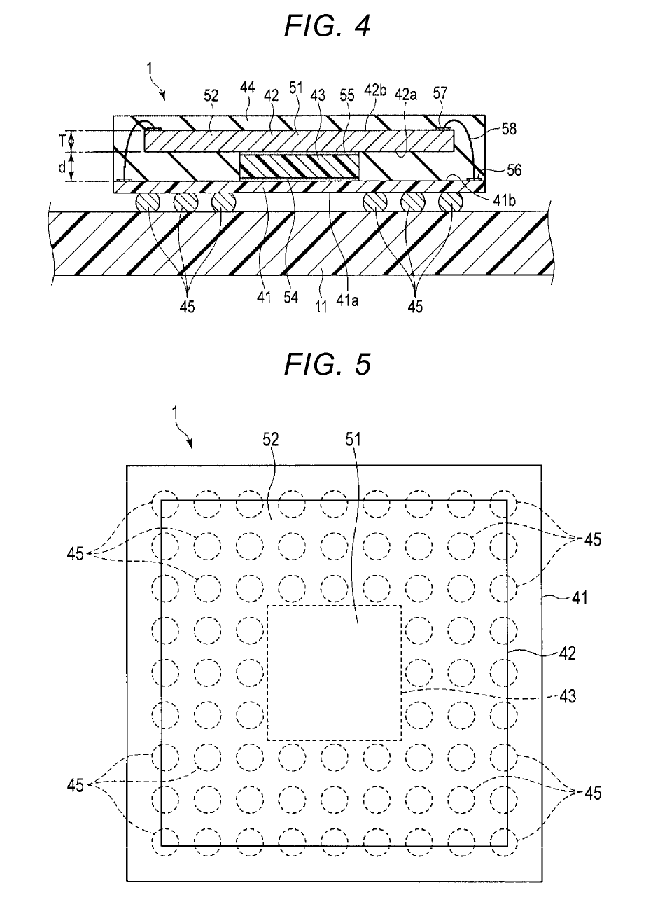

FIG. 4 illustrates a cross-sectional view of the semiconductor package 1. FIG. 5 illustrates a plan view of the semiconductor package 1 with a mold 44 removed therefrom for the sake of convenience in description. As illustrated in FIGS. 4 and 5, the semiconductor package 1 includes a substrate 41 (substrate board), a silicon chip 42, a support portion 43, the mold 44, and a plurality of solder joints 45.

The substrate 41 is a wiring substrate, for example, formed in a shape of rectangular flat plate, including a base made of resin (for example, glass epoxy material) and a wiring pattern (rewiring layer) provided on the base. The substrate 41 has a first surface 41a and a second surface 41b positioned opposite to the first surface 41a. The first surface 41a is positioned outside the mold 44 and forms the rear surface of the semiconductor package 1, facing the circuit substrate 11. The second surface 41b is a mounting surface where the silicon chip 42 is mounted, covered with the mold 44.

As illustrated in FIG. 4, the plural solder joints 45 are provided on the first surface 41a of the substrate 41 and electrically connected to the circuit substrate 11. In the embodiment, the semiconductor package 1 is a so-called Ball Grid Array (BGA) package. In short, the solder joint 45 is, for example, a soldering ball provided on the first surface 41a of the substrate 41. The semiconductor package 1 is not restricted to the BGA package but may be a Land Grid Array (LGA) package or a Quad For Non-lead (QFN) package. Here, the solder joint 45 is, for example, a land to which a bump is connected.

As illustrated in FIGS. 4 and 5, the plural solder joints 45 are aligned, for example, on the first surface 41a in a lattice shape. The solder joints 45 are not necessarily provided on the whole area of the first surface 41a but may be partially provided. In the embodiment, the solder joints 45 are provided on an area excluding an area overlapping with the support portion 43 described later in a thickness direction of the substrate 41.

The silicon chip 42 (semiconductor chip) is formed in a shape of rectangular flat plate. The silicon chip 42 is, for example, a semiconductor element serving as a controller, a memory, or a data transfer unit. In other words, the silicon chip 42 may be any of the controller 21, the semiconductor memory 22 (NAND memory), and the DRAM 23 mentioned above. The silicon chip 42 faces the second surface 41b of the substrate 41. The silicon chip 42 is one example of a heating component which heats at the operation time.

The support portion 43 (interposer, spacer, relay member, insertion member) is formed in a shape of rectangular flat plate. The support portion 43 is formed in a smaller outer shape than the silicon chip 42 and formed, for example, corresponding to a center portion 51 of the silicon chip 42. The “formed in a smaller outer shape” means “the outer periphery is small in size” or “the area (projected area) on a flat surface view is small.”

As illustrated in FIG. 4, the support portion 43 is provided between the second surface 41b of the substrate 41 and the center portion 51 of the silicon chip 42 and supports the silicon chip 42 from the second surface 41b of the substrate 41 at a distant position (floating position). According to this structure, an interstice, where some of the mold 44 enters, is formed between a peripheral portion 52 of the silicon chip 42 and the second surface 41b of the substrate 41. Here, the “peripheral portion of the silicon chip” means an area between the outer periphery of the silicon chip 42 and the center portion 51.

A distance d between the silicon chip 42 and the second surface 41b of the substrate 41 is, for example, substantially equal to or greater than a thickness T of the silicon chip 42. The support portion 43 is made of, for example, silicon but not restricted to this; for example, the support portion 43 may be made of resin or glass. When the support portion 43 is made of a material other than silicon, the support portion 43 may be formed of a material softer than the silicon chip 42.

As illustrated in FIG. 4, the silicon chip 42 covers the plural solder joints 45. Here, “cover the solder joints” means that the silicon chip 42 overlaps with the solder joints 45 in a thickness direction of the substrate 41. In the embodiment, the silicon chip 42 overlaps also with the solder joints 45 positioned in the outermost periphery, of the plural solder joints 45.

On the other hand, the support portion 43 has a smaller outer shape than the silicon chip 42 and does not cover at least one of the solder joints 45 covered with the silicon chip 42. In the embodiment, the solder joints 45 are provided getting out of the underneath of the support portion 43 as mentioned above. As the result, the support portion 43 covers none of the solder joints 45.

As illustrated in FIG. 4, a first fixing portion 54 is provided between the second surface 41b of the substrate 41 and the support portion 43. The first fixing portion 54 is made of, for example, a die bonding material: bonding agent or adhesive sheet (mount film). The first fixing portion 54 is to fix the support portion 43 on the second surface 41b of the substrate 41.

Similarly, a second fixing portion 55 is provided between the support portion 43 and the silicon chip 42. The second fixing portion 55 is made of, for example, a die bonding material: bonding agent or adhesive sheet (mount film). The second fixing portion 55 fixes the silicon chip 42 to the support portion 43.

As illustrated in FIG. 4, the second surface 41b of the substrate 41 includes a first pad 56. The silicon chip 42 includes a second pad 57. More specifically, the silicon chip 42 includes a first surface 42a facing the support portion 43 and a second surface 42b positioned at the side opposite to the first surface 42a. The second pad 57 is provided on the second surface 42b of the silicon chip 42. A bonding wire 58 is provided between the first pad 56 and the second pad 57. According to this, the silicon chip 42 is electrically connected to the substrate 41 through the bonding wire 58.

As illustrated in FIG. 4, the mold 44 covers the silicon chip 42, the support portion 43, and the bonding wire 58 integrally. A part of the mold 44 enters a space between the peripheral portion 52 of the silicon chip 42 and the second surface 41b of the substrate 41. The mold 44 is made of, for example, resin and softer than, for example, the silicon chip 42 and the support portion 43. The mold 44 is more deformable according to the shape of the substrate 41 when the substrate 41 thermally expands, compared to the silicon chip 42 and the support portion 43.

Next, a function of the semiconductor package 1 will be described.

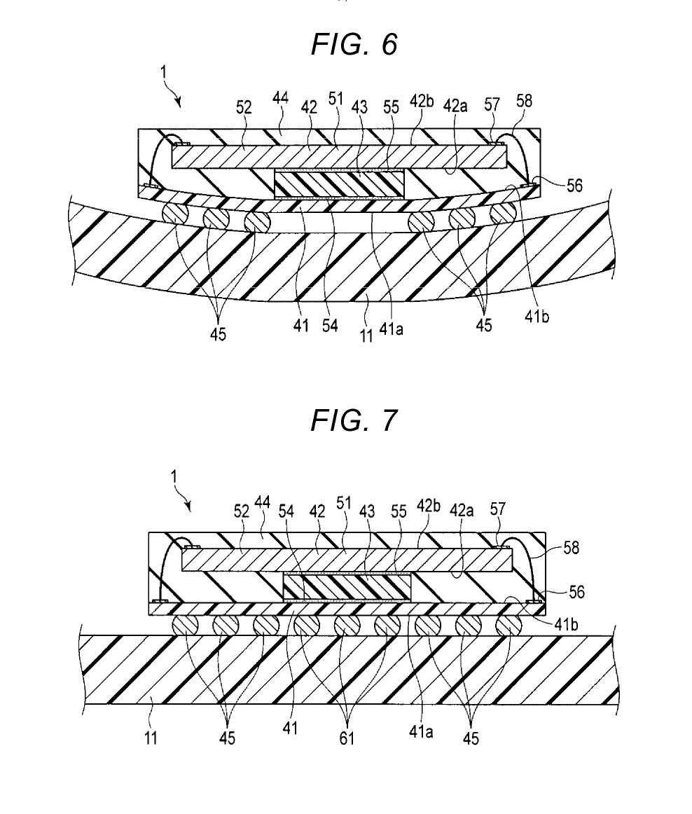

FIG. 6 illustrates an example of deformation of the semiconductor package 1 when the semiconductor package 1 generates heat. The semiconductor package 1 generates heat during the operation. According to this, the substrate 41 of the semiconductor package 1 may be warped in the thickness direction of the substrate 41 according to the thermal expansion.

In the embodiment, the silicon chip 42 is distant from the second surface 41b of the substrate 41. Therefore, the substrate 41 of the semiconductor package 1 is unlikely to be constrained by the silicon chip 42 at the thermal expansion, and compared with the case where the silicon chip 42 is adjacent to the substrate 41, the substrate 41 may be deformed comparatively freely. Therefore, a large distortion is unlikely to occur in the substrate 41 and the solder joints 45, hence to reduce the accumulation of fatigue in the solder joints 45.

According to the semiconductor package 1 thus configured, reliability may be improved. For a comparison, the structure where the silicon chip 42 is directly mounted on the second surface 41b of the substrate 41 without the support portion 43 will be considered. The silicon chip 42 is generally harder than the substrate 41. Therefore, when the semiconductor package 1 generates heat and the substrate 41 will be deformed according to the thermal expansion, the silicon chip 42 strongly constrains the second surface 41b of the substrate 41. As the result, fatigue accumulates in the solder joints 45 and when the semiconductor package is used for a long time, a break may occur in the solder joints 45 positioned just beneath the silicon chip 42.

Then, the semiconductor package 1 according to the embodiment includes the support portion 43 between the second surface 41b of the substrate 41 and the silicon chip 42. The silicon chip 42 is distant from the second surface 41b of the substrate 41, because the support portion 43 is disposed therebetween. According to this structure, as illustrated in FIG. 6, the substrate 41 is unlikely to be constrained by the silicon chip 42 at the thermal expansion of the substrate 41, and fatigue is unlikely to accumulate in the solder joints 45. Therefore, even if the semiconductor package is used for a long time, the solder joints 45 is unlikely to fail and a long-term reliability may be improved in the semiconductor package 1. In short, according to the above structure, thermal fatigue lifetime may be prolonged in the solder joints 45.

Further, when the silicon chip 42 is distant from the second surface 41b of the substrate 41, the amount of heat transmitted from the silicon chip 42 to the substrate 41 becomes less. Therefore, the deformation of the substrate 41 itself according to the thermal expansion becomes smaller. From this viewpoint, fatigue is unlikely to accumulate in the solder joints 45, thereby the long-term reliability of the semiconductor package 1 can be further improved.

In the embodiment, the support portion 43 has a smaller outer shape than the silicon chip 42 and does not cover at least one of the solder joints 45 covered with the silicon chip 42. According to this structure, even if the support portion 43 is formed of a hard material like, for example, silicon, the solder joints 45 are unlikely to be constrained by the support portion 43 and fatigue is unlikely to accumulate in the solder joints 45. Therefore, the long-term reliability of the semiconductor package 1 may be further improved.

In the embodiment, the plural solder joints 45 are provided in the area excluding the area overlapping with the support portion 43 in the thickness direction of the substrate 41. According to this structure, the solder joints 45 are unlikely to be constrained by the support portion 43.

In the embodiment, the distance d between the silicon chip 42 and the second surface 41b of the substrate 41 is schematically equal to or more than the thickness T of the silicon chip 42. According to this structure, a distance enough to absorb the warpage of the substrate 41 is secured between the silicon chip 42 and the second surface 41b of the substrate 41. Therefore, fatigue is unlikely to accumulate in the solder joints 45.

Next, a semiconductor package 1 according to first to third modified examples of the first embodiment and second to eighth embodiments will be described. The same reference codes are attached to the components having the same or similar functions as those of the first embodiment and the description thereof is omitted. Other components than the component described later are the same as the first embodiment.

### First Modified Example

FIG. 7 illustrates a semiconductor package 1 according to a first modified example of the first embodiment. In this modified example, solder joints 61 are provided also in the area overlapping with the support portion 43 in the thickness direction of the substrate 41. The solder joints 61 are, for example, additional solder joints for reinforcement of ground, or dummy solder joints for reinforcement of connection. According to the structure, the underneath portion of the support portion 43 may be used for reinforcing the ground and the connection. The solder joints 61 may be a solder joint for signal or power.

### Second Modified Example

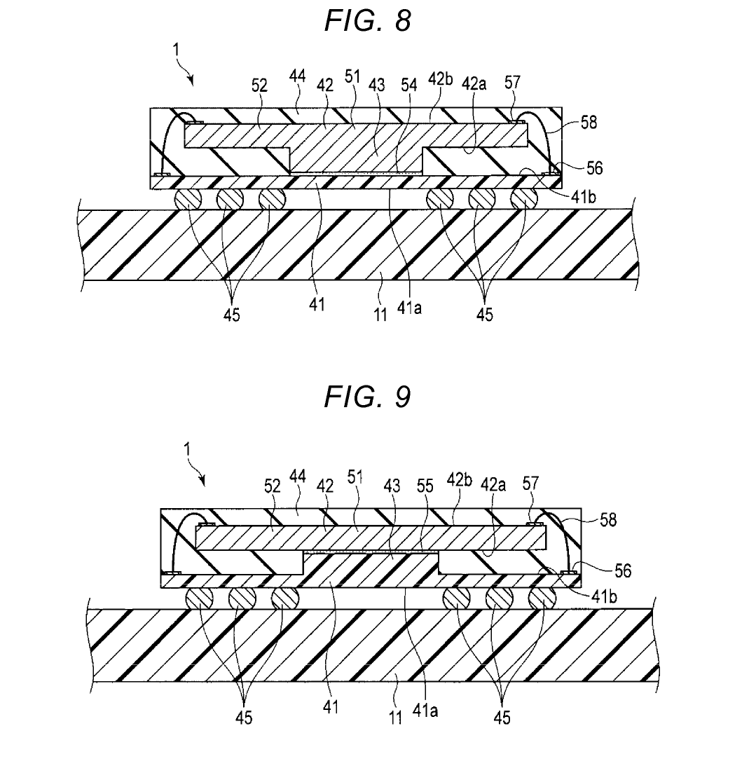

FIG. 8 illustrates a semiconductor package 1 according to a second modified example of the first embodiment. In this modified example, the support portion 43 is formed integrally with the silicon chip 42. In short, the support portion 43 is a convex portion provided on the first surface 42a of the silicon chip 42. This structure also may achieve substantially the same function as the first embodiment.

### Third Modified Example

FIG. 9 illustrates a semiconductor package 1 according to a third modified example of the first embodiment. In this modified example, the support portion 43 is formed integrally with the circuit substrate 11. In short, the support portion 43 is a convex portion provided on the second surface 41b of the substrate 41. The support portion 43 may be formed, for example, by disposing a resist thicker on the surface of the substrate 41. This structure also may achieve substantially the same function as the first embodiment.

### Second Embodiment

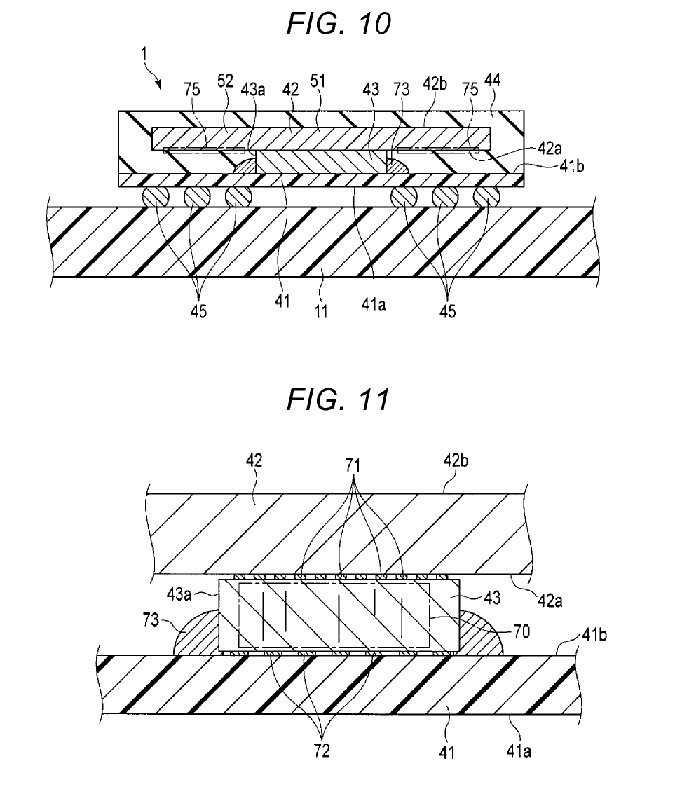

FIGS. 10 and 11 illustrate a semiconductor package 1 according to a second embodiment. In the embodiment, the support portion 43 has a function as an intermediate material that electrically connects the silicon chip 42 to the second surface 41b of the substrate 41.

More specifically, the support portion 43 is made of silicon and has a relay wiring 70 (electric connection path) for electrically connecting the silicon chip 42 to the second surface 41b of the substrate 41. The relay wiring 70 may be also formed by, for example, a via or a conductor layer provided on the support portion 43.

A plurality of first electric connection portions 71 are provided between the silicon chip 42 and the support portion 43. Each of the first electric connection portions 71 is connected to the relay wiring 70. Similarly, a plurality of second electric connection portions 72 are provided between the support portion 43 and the second surface 41b of the substrate 41. Each of the second electric connection portions 72 is connected to the relay wiring 70. Each of the first electric connection portions 71 and the second electric connection portions 72 is, for example, a gold bump. The relay wiring 70 electrically connects the plural first electric connection portions 71 and the plural second electric connection portions 72.

As illustrated in FIG. 11, each of the second electric connection portions 72 is larger than each of the first electric connection portions 71. For example, the outer shape of the gold bump forming the second electric connection portion 72 is larger than the outer shape of the gold bump forming the first electric connection portion 71. According to this, the joint strength between the support portion 43 and the second surface 41b of the substrate 41 is larger than the joint strength between the silicon chip 42 and the support portion 43. Further, the number of the second electric connection portions 72 is smaller than the number of the first electric connection portions 71.

As illustrated in FIG. 10, a reinforcement portion 73 is provided between the second surface 41b of the substrate 41 and the side surface 43a of the support portion 43. The “side surface of the support portion” means the circumferential surface of the support portion 43 extending in the thickness direction of the substrate 41. The reinforcement portion 73 is provided around the circumference of the support portion 43 (for example, the whole circumference), to fix the support portion 43 and the second surface 41b of the substrate 41. The reinforcement portion 73 is, for example, a bonding agent of resin.

The reinforcement portion 73 does not contact the silicon chip 42. In other words, an interstice is provided between the first surface 42a of the silicon chip 42 and the reinforcement portion 73. At least a part of an electric circuit 75 of the silicon chip 42 is formed on the first surface 42a of the silicon chip 42. In short, the reinforcement portion 73 fixes the support portion 43 on the substrate 41 while avoiding the electric circuit 75 of the silicon chip 42.

According to the structure, similarly to the first embodiment, reliability of the semiconductor package 1 may be improved. Further, in the embodiment, the support portion 43 includes the relay wiring 70 which electrically connects the silicon chip 42 to the second surface 41b of the substrate 41. According to the structure, a transmission path between the silicon chip 42 and the substrate 41 may be shortened compared with a structure in which the bonding wire 58 is provided. This may improve the operation speed in the semiconductor package 1.

According to the structure, there is no necessity to provide the silicon chip 42 with the bonding wire 58; therefore, the mold 44 covering the upper portion of the silicon chip 42 may be thinned. Accordingly, the semiconductor package 1 may be thinned.

The silicon chip 42 and the support portion 43 made of silicon are substantially the same or similar to each other in the linear expansion coefficient. Therefore, in the thermal expansion of the semiconductor package 1, a large force caused by the thermal expansion is unlikely to be applied between the silicon chip 42 and the support portion 43. On the other hand, a comparatively large force is likely to be generated between the substrate 41 made of resin and the support portion 43 made of silicon because the linear expansion coefficient is different from each other.

In the embodiment, each of the second electric connection portions 72 is formed larger than each of the first electric connection portions 71. According to this, the joint strength between the support portion 43 and the substrate 41 is set larger than the joint strength between the silicon chip 42 and the support portion 43. According to this structure, a failure is unlikely to occur in the electric connection between the silicon chip 42 and the substrate 41, and the long-term reliability of the semiconductor package 1 can be further improved.

In the embodiment, the number of the second electric connection portions 72 is smaller than the number of the first electric connection portions 71. According to this structure, a possibility of a failure between the support portion 43 and the substrate 41 may be reduced. By decreasing the number of the second electric connection portions 72, the size of each of the second electric connection portions 72 may be easily formed larger than the size of each of the first electric connection portions 71. According to this, the long-term reliability of the semiconductor package 1 may be further improved.

In the embodiment, the reinforcement portion 73 is provided between the second surface 41b of the substrate 41 and the side surface 43a of the support portion 43. According to the structure, the fixing strength of the support portion 43 to the substrate 41 may be enhanced and a possibility may be reduced that a failure may occur between the support portion 43 and the substrate 41 according to the thermal expansion.

### Third Embodiment

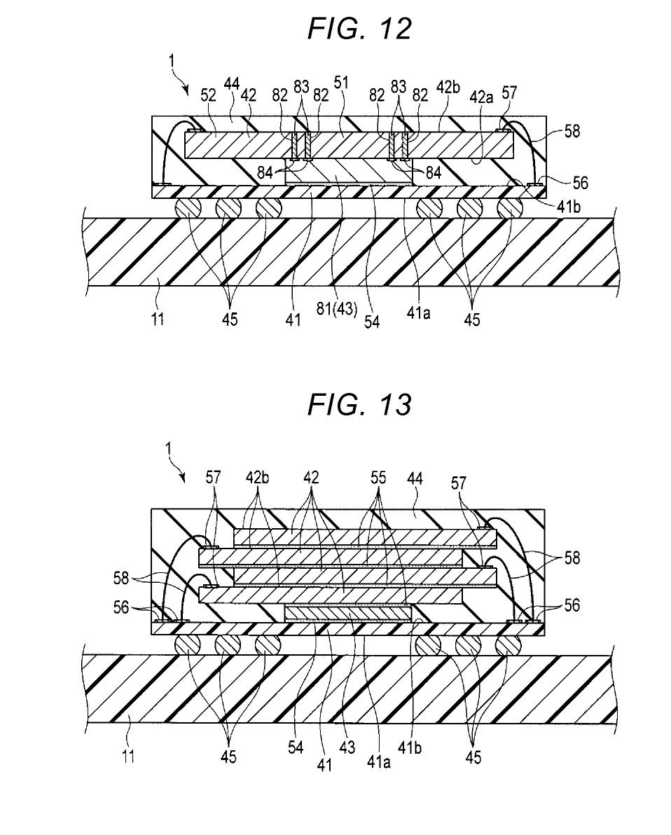

FIG. 12 illustrates a semiconductor package 1 according to a third embodiment. In this embodiment, the silicon chip 42 is a first silicon chip 42. The support portion 43 is a second silicon chip 81 serving as a controller, a memory, or a data transfer unit. In short, the first silicon chip 42 is stacked on the second silicon chip 81 smaller than the first silicon chip 42 at a distance from the second surface 41b of the substrate 41.

The second silicon chip 81 (second semiconductor chip) is a semiconductor element formed in a shape of rectangular flat plate. The second silicon chip 81 may be any of the controller 21, the semiconductor memory 22 (NAND memory), and the DRAM 23 as mentioned above. The second silicon chip 81 may have the same function as the first silicon chip 42 or a different function from the above.

The first silicon chip 42 includes a through-hole 82 and a via 83 formed inside the through-hole 82 in the area overlapping with the second silicon chip 81. The through-hole 82 and the via 83 penetrate the first silicon chip 42 in the thickness direction of the substrate 41, facing the second silicon chip 81.

The second silicon chip 81 includes an electric connection portion 84 electrically connected to the via 83. According to this structure, the second silicon chip 81 is electrically connected to the substrate 41, for example, through the via 83 and the first silicon chip 42.

Further according to this structure, the reliability of the semiconductor package 1 may be improved, similarly to the above first embodiment. Further, in the embodiment, the support portion 43 is the second silicon chip 81 serving as a controller, a memory, or a data transfer unit. According to this structure, the function and the performance of the semiconductor package 1 may be expanded while securing the reliability.

In the embodiment, the first silicon chip 42 is provided with the via 83 at the position facing the second silicon chip 81. The second silicon chip 81 is electrically connected to the substrate 41 through the via 83. According to this structure, the second silicon chip 81 disposed between the first silicon chip 42 and the substrate 41 may be electrically connected to the substrate 41 more reliably.

### Fourth Embodiment

FIG. 13 illustrates a semiconductor package 1 according to a fourth embodiment. In this embodiment, the semiconductor package 1 includes a plurality of first silicon chips 42. The plural first silicon chips 42 are, for example, the semiconductor memory 22. The plural first silicon chips 42 are mutually deviated and stacked in the thickness direction of the substrate 41. A second pad 57 to which the bonding wire 58 is connected is provided on the second surface 42b of the first silicon chip 42.

In the embodiment, the support portion 43 may be simply a spacer that does not work as the silicon chip, similarly to the first embodiment, or a semiconductor element serving as the second silicon chip 81, similarly to the third embodiment. The second silicon chip 81 may be the semiconductor memory 22, similarly to the first silicon chip 42, or the controller 21 or the DRAM 23.

According to this structure, the reliability of the semiconductor package 1 may be improved, similarly to the first embodiment. In the embodiment, the long-term reliability may be improved in the semiconductor package 1 including the plural semiconductor memories 22.

### Fifth Embodiment

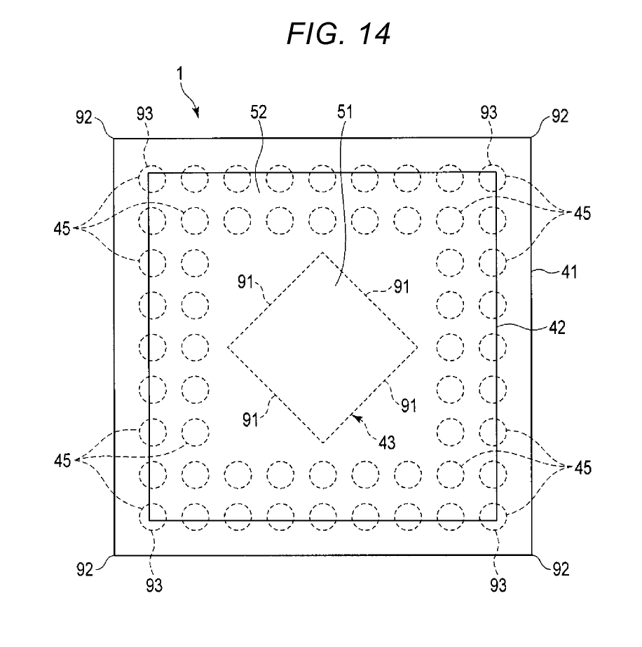

FIG. 14 illustrates a semiconductor package 1 according to a fifth embodiment. FIG. 14 illustrates the semiconductor package 1 without the mold 44, for the sake of convenience in description. In the embodiment, each of the substrate 41, the silicon chip 42, and the support portion 43 is formed in a rectangular shape. As illustrated in FIG. 14, the support portion 43 is positioned so that each side 91 of the support portion 43 faces each corner 92 of the substrate 41. The support portion 43 is positioned (rotated), for example, at an angle of 45 degree with respect to the substrate 41.

According to this structure, the reliability in the semiconductor package 1 may be improved, similarly to the first embodiment.

Generally, of the plural solder joints 45, fatigue is likely to accumulate in the solder joints 93 near the corners 92 of the substrate 41 and cause a failure. In the embodiment, by positioning the support portion 43 at a slant to the substrate 41, a distance between the solder joint 93 near the corner 92 of the substrate 41 and the support portion 43 is set as large as possible. According to this, the solder joints 93 are unlikely to be affected by the support portion 43 and the fatigue is unlikely to accumulate in the solder joints 93. Thus, the long-term reliability may be further improved in the semiconductor package 1. The structure of positioning the support portion 43 at a slant to the substrate 41 like the embodiment may be also applied to all the other embodiments and the modified examples.

### Sixth Embodiment

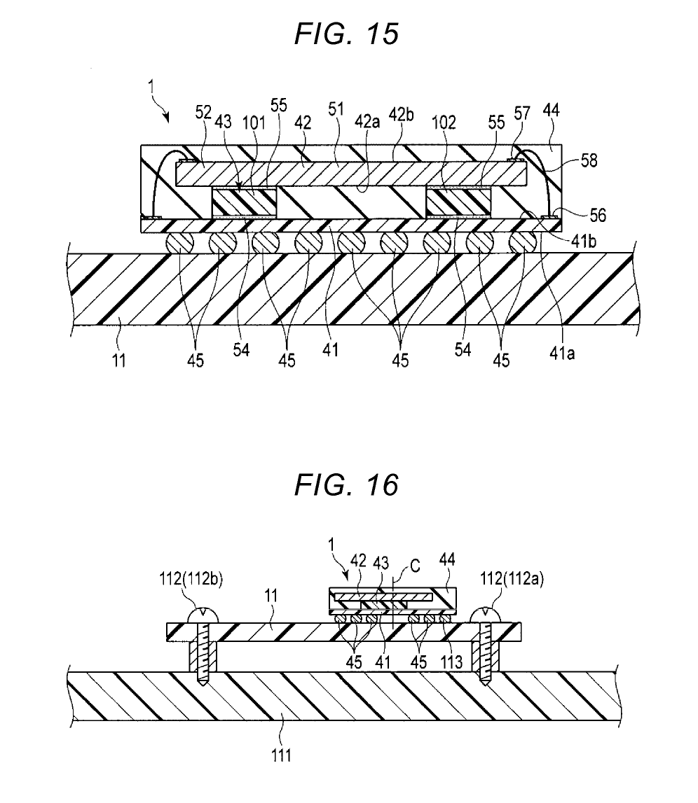

FIG. 15 illustrates a semiconductor package 1 according to a sixth embodiment. In the embodiment, the support portion 43 is separated into a plurality of support pieces 101 and 102 so as to avoid an underneath portion of the center portion 51 of the silicon chip 42. The support pieces 101 and 102 support the peripheral portion 52 of the silicon chip 42. Instead of this structure, the support portion 43 may be formed in a frame shape in a way of avoiding the underneath portion of the center portion 51 of the silicon chip 42.

According to this structure, the reliability of the semiconductor package 1 may be improved, similarly to the first embodiment. Further, according to the above structure, the solder joints 45 positioned in the center portion of the substrate 41 are not constrained by the support portion 43. Especially, when there are the solder joints 45 that should be protected in the center portion of the substrate 41, the structure according to the embodiment may be applied, hence to improve the long-term reliability of the semiconductor package 1.

### Seventh Embodiment

FIGS. 16 and 17 illustrate a semiconductor package 1 according to a seventh embodiment. FIG. 17 illustrates the semiconductor package 1 without the mold 44, for the sake of convenience in description. In the embodiment, the circuit substrate 11 is fixed to further another circuit substrate 111. The circuit substrate 11 is fixed to, for example, the circuit substrate 111 through a plurality of fixing units 112 like screw. The plural fixing units 112 include one first fixing unit 112a and remaining second fixing units 112b. The first fixing unit 112a is positioned nearest to the semiconductor package 1, of the plural fixing units 112.

In the embodiment, the silicon chip 42 and the support portion 43 are positioned apart from the center C of the substrate 41 in a direction away from the first fixing unit 112a inside the semiconductor package 1.

According to this structure, the reliability of the semiconductor package 1 may be improved, similarly to the first embodiment. Here, of the plural solder joints 45, the fatigue is likely to accumulate in the solder joint 113 near to the first fixing unit 112a, the silicon chip 42 and the support portion 43 are positioned away from the solder joint 113 near the first fixing unit 112a. This may relax the fatigue accumulated in the solder joint 113 near the first fixing unit 112a, and the long-term reliability of the semiconductor package 1 can be further improved.

### Eighth Embodiment

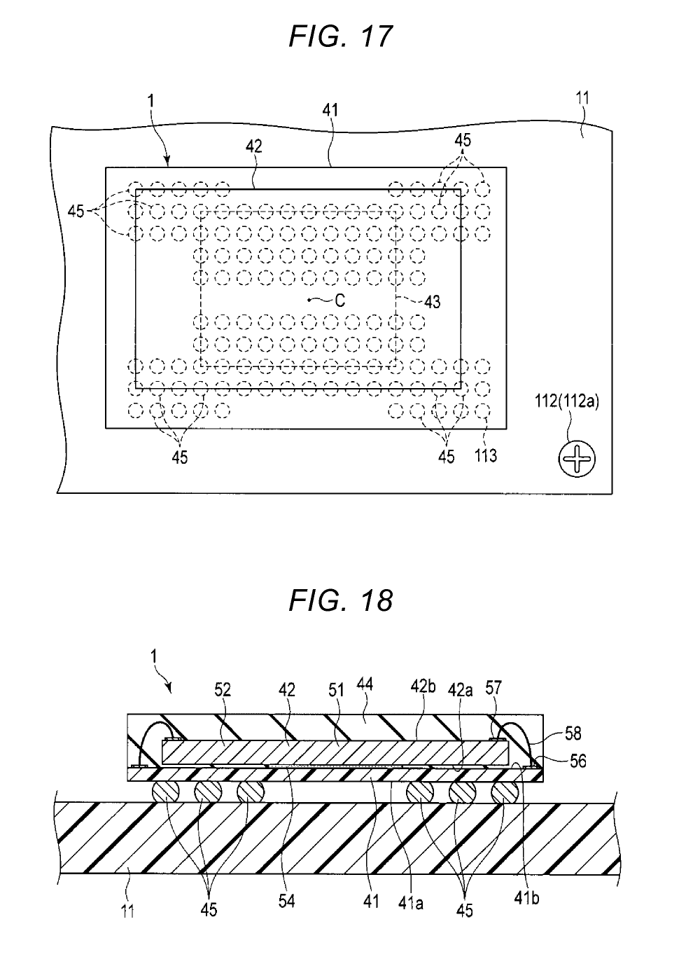

FIG. 18 illustrates a semiconductor package 1 according to an eighth embodiment. In the embodiment, the silicon chip 42 is directly fixed to the second surface 41b of the substrate 41 by a fixing portion 54. The fixing portion 54 is provided between the center portion 51 of the silicon chip 42 and the second surface 41b of the substrate 41, to fix the center portion 51 of the silicon chip 42 and the second surface 41b of the substrate 41. The fixing portion 54 is not positioned between the peripheral portion 52 of the silicon chip 42 and the second surface 41b of the substrate 41. In other words, the peripheral portion 52 of the silicon chip 42 is not fixed to the second surface 41b of the substrate 41. The fixing portion 54 has an outer shape smaller than the silicon chip 42.

According to this structure, the substrate 41 and the solder joints 45 are unlikely to sustain a large distortion according to the thermal expansion, and the fatigue is unlikely to accumulate in the solder joints 45, as compared with the case where the whole surface of the silicon chip 42 is fixed to the substrate 41. Thus, the long-term reliability of the semiconductor package 1 may be improved in.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device package comprising:
a substrate having a first surface and a second surface that is opposite to the first surface;
a plurality of solder joints disposed on the first surface of the substrate;
a semiconductor chip disposed above the second surface of the substrate; and
a support member disposed between the second surface of the substrate and the semiconductor chip,
wherein at least one of the solder joints is in contact with the first surface of the substrate opposite to a region on the second surface in which the support member is not disposed.

2. The semiconductor device package according to claim 1, wherein
all of the solder joints are in contact with the first surface of the substrate opposite to the region on the second surface.

3. The semiconductor device package according to claim 1, wherein
the support member is disposed in a center region of the second surface of the substrate.

4. The semiconductor device package according to claim 1, wherein
the support member is disposed, such that each side thereof is not parallel to sides of the substrate.

5. The semiconductor device package according to claim 1, further comprising:
a resin layer entirely enclosing the semiconductor chip and the support member therein, apart of the resin layer being disposed between the second surface of the substrate and the semiconductor chip.

6. The semiconductor device package according to claim 1, wherein
an area of the semiconductor chip connected to the support member is smaller than an area of the semiconductor chip that is not connected to the support member.

7. The semiconductor device package according to claim 1, wherein
a thickness of the support member is greater than a thickness of the semiconductor chip.

8. The semiconductor device package according to claim 1, wherein
the support member has a third surface that faces the second surface of the substrate and a fourth surface that faces the semiconductor chip, and includes a wiring connecting between the third surface and fourth surface.

9. The semiconductor device package according to claim 8, further comprising:
a plurality of first electrical connectors disposed between the fourth surface of the support member and the semiconductor chip; and
a plurality of second electrical connectors disposed between the second surface of the substrate and the third surface of the support member.

10. The semiconductor device package according to claim 8, further comprising:
a reinforcement member connecting the second surface of the substrate and a peripheral surface of the support member.

11. The semiconductor device package according to claim 1, wherein
the semiconductor chip is a first semiconductor chip, and
the support member includes a second semiconductor chip that serves as a controller, a memory, or a data transfer unit.

12. The semiconductor device package according to claim 11, wherein
the first semiconductor chip includes a via penetrating the first semiconductor chip, and
the second semiconductor chip is electrically connected to the substrate through the via.

13. A semiconductor device package comprising:
a substrate having a first surface and a second surface that is opposite to the first surface;
a plurality of solder joints disposed on the first surface of the substrate;
a semiconductor chip disposed above the second surface of the substrate; and
a support member that is disposed between the second surface of the substrate and the semiconductor chip,
wherein an area of the semiconductor chip connected to the support member is smaller than an area of the semiconductor chip that is not connected to the support member.

14. The semiconductor device package according to claim 13, wherein
all of the solder joints are in contact with the first surface of the substrate opposite to the region on the second surface in which the support member is not disposed.

15. The semiconductor device package according to claim 13, wherein
the support member is disposed in a center region of the second surface of the substrate.

16. The semiconductor device package according to claim 13, wherein
the support member is disposed, such that each side thereof is not parallel to sides of the substrate

17. The semiconductor device package according to claim 13, wherein
a thickness of the support member is greater than a thickness of the semiconductor chip.

18. The semiconductor device package according to claim 13, wherein
the support member has a third surface that faces the second surface of the substrate and a fourth surface that faces the semiconductor chip, and includes a wiring connecting between the third surface and fourth surface.

19. The semiconductor device package according to claim 18, wherein
a plurality of first electrical connectors disposed between the fourth surface of the support member and the semiconductor chip; and
a plurality of second electrical connectors disposed between the second surface of the substrate and the third surface of the support member.

20. An electronic device comprising:
a host device having a plurality of connectors; and
a plurality of semiconductor devices, each being connected to one of the connectors and including a circuit board and a semiconductor chip package connected to the circuit board,
wherein the semiconductor chip package includes
a substrate having a first surface facing the circuit board and a second surface that is opposite to the first surface,
a plurality of solder joints disposed between the first surface of the substrate and the circuit board,
a semiconductor chip disposed above the second surface of the substrate, and
a support member that is disposed between the second surface of the substrate and the semiconductor chip, and
wherein at least one of the solder joints is in contact with the first surface of the substrate opposite to a region on the second surface in which the support member is not disposed.
